(19) United States
(12) Patent Application Publication
(10) Pub. No.: US 2026/0099013 A1
(43) Pub. Date: Apr. 9, 2026

(54) SEMICONDUCTOR ASSEMBLIES AND SEMICONDUCTOR PACKAGES

(71) Applicant: Technische Universitaet Dresden, Koerperschaft des Oeffentlichen Rechts, Dresden (DE)

(72) Inventors: Sujay Ashok CHARANIA, Dresden (DE); Johann Wolfgang BARTHA, Dresden (DE); Dirk PLETTEMEIER, Dresden (DE)

(21) Appl. No.: 19/348,516

(22) Filed: Oct. 2, 2025

(30) Foreign Application Priority Data
Oct. 4, 2024 (DE) 10 2024 128 738.1

(51) Int. Cl. G02B 6/42; G02B 6/43; H01L 23/00; H01L 25/16

(52) U.S. Cl. CPC G02B 6/4206; G02B 6/43; H10W 90/00; H10W 90/722

(57) ABSTRACT

A semiconductor assembly may comprise: a first semiconductor substrate, the first semiconductor substrate comprising a first through-hole, wherein a first optical waveguide structure is formed in the first through-hole for guiding optical waves; a second semiconductor substrate, the second semiconductor substrate comprising a second through-hole, wherein a second optical waveguide structure is formed in the second through-hole for guiding optical waves; wherein the first semiconductor substrate and the second semiconductor substrate are arranged at a distance from each other and such that optical waves coupled out from the first optical waveguide structure are coupled into the second optical waveguide structure; and at least one first optical lens configured to refract the optical waves coupled out from the first optical waveguide structure in the direction of the second optical waveguide structure and/or at least one second optical lens configured to refract the optical waves coupled out from the first optical waveguide structure in the direction of the second optical waveguide structure.

The invention relates to semiconductor assemblies and semiconductor packages.

Semiconductor back-end-of-line (BEOL) interconnects should, on the one hand, fully enable the utilization of current front-end components, such as transistors, by enabling high-speed and broadband interconnects, and, on the other hand, should be future-proof in the sense that they allow the growth of front-end components and are not the limiting factor in terms of bandwidth, component footprint and power consumption.

In the current monolithic and heterogeneous chip integration, 3D chip stacking (3-dimensional stacking of chips) is of great importance. Often several special processors, memories, sensors and other electronic components are to be interconnected.

Multi-chip solutions are envisaged that form a multi-chip module on interposers. Communication between these chips takes place at high data rates. As component density and bandwidth requirements increase, a faster and more efficient network of interconnect lines is required to connect the distributed components on chips and interposers.

The performance growth of current BEOL interconnects is stagnating and does not allow the full potential of ultra-fast front-end components to be utilized due to their limited bandwidth, larger footprint, and high power consumption.

This problem has traditionally been addressed through the use of on-chip optical interconnects.

However, conventional on-chip optical interconnects are limited to light distribution on a single layer of a chip using single-layer photonic components.

The following is an overview of various conventional approaches to information transmission in a three-dimensional chip stack (3D chip stack):
1. Converting the optical signal into an electrical form, transferring it to other components/layers and/or chips, and then converting the signal back into the optical form.
   With this approach, the reduction in data rate and bandwidth loss when converting the signal from the optical region to the electrical region and back to the optical region are very high. Furthermore, the additional electrical components required limit the speed of data transmission and reduce the energy efficiency of the overall system at the expense of increased space requirements.
2. Use of a grating coupler that enables a 90° change in direction of the optical signal.
   Grating couplers are very narrow-band components and can only be used outside this already very short wavelength range with high signal losses. In addition, wave propagation is only possible in two directions without higher transmission losses. In the third direction, high transmission losses occur, which cannot be avoided.
3. Use of photonic bondwires (wirebonds) of an optical free-space connection, which is typically realized by means of printed 2-photon lithography.
   Photonic wirebonds are limited to the formation of optical waveguides in free space. It is not possible to create optical connections within a chip or between two layers of a chip using this approach.
4. Mainly electrical solution with optics limited to a single layer (silicon (Si) and IV/IV photonics such as silicon-germanium (SiGe)).
   Silicon photonics or photonics with other III-V semiconductor materials is limited to 2D planar optical solutions and is usually restricted to the top layer of the semiconductor chip. With this approach, it is not possible to create a monolithically integrated optical interconnect between layers within a chip.
5. Complete abandonment of optical connections within the chip (exclusively electrical solution).
   The bandwidth of the electrical connections is very low compared to the bandwidth of the optical connections. The complete omission of an optical connection is disadvantageous for current and future computer applications that require low latency, high bandwidth, small footprint, and high energy efficiency. The inclusion of optical interconnects makes it possible to overcome the above limitations of the current state of the art hardware.

Various embodiments provide semiconductor assemblies that address and at least partially improve upon various disadvantageous aspects of conventional approaches.

Various aspects of the present disclosure provide monolithically integrable three-dimensional (3D) chip stack coupling elements that enable variable (optical) power ratio coupling between multiple layers of a chip, as well as between multiple chips.

Various aspects of the present disclosure enable an optical redistribution layer (ORDL) to be configured without intermediate electrical conversion.

Various aspects of the present disclosure enable an end-to-end optical interconnect for both intra-chip stacks and inter-chip stacks.

Various aspects of this disclosure increase security against unintentional data loss/theft of multi-chip modules.

Uninterrupted, low-latency communication between multiple components on a chip stack is the requirement for current hardware to achieve the goals for high-speed and high-performance computing. The ability to route optical interconnects within a semiconductor assembly (e.g., a semiconductor substrate (e.g., an interposer) or a semiconductor chip) or semiconductor chip stack (comprising one or more semiconductor substrates (e.g., comprising one or more interposers) and/or comprising one or more semiconductor chips) is of significant importance.

According to various aspects of the present disclosure, a semiconductor assembly is provided. The semiconductor assembly may comprise a first semiconductor substrate having a front side and a back side opposite to the front side. The first semiconductor substrate comprises a first through-hole extending from the front side of the first semiconductor substrate to the back side of the first semiconductor substrate. A first optical waveguide structure is formed in the first through-hole for guiding optical waves between the front surface of the first semiconductor substrate and the back surface of the first semiconductor substrate. The semiconductor assembly may further comprise a second semiconductor substrate having a front side and a back side opposite to the front side. The second semiconductor substrate has a second through-hole extending from the front side of the second semiconductor substrate to the back side of the second semiconductor substrate. A second optical waveguide structure is formed in the second through-hole for guiding optical waves between the front surface of the second semiconductor substrate and the back surface of the second semiconductor substrate. The first semiconductor substrate and the second semiconductor substrate are arranged at a distance from each other and (relative) to each other such that optical waves coupled out from the first optical waveguide structure are coupled into the second optical waveguide structure. The semiconductor assembly may further comprise at least one first optical lens or at least one first optical meta-structure configured to refract the optical waves coupled out from the first optical waveguide structure in the direction of the second optical waveguide structure, and/or at least one second optical lens or at least one second optical meta-structure configured to refract the optical waves coupled out from the first optical waveguide structure in the direction of the second optical waveguide structure.

Examples of embodiments of the invention are shown in the figures and are explained in more detail below.

The figures show in

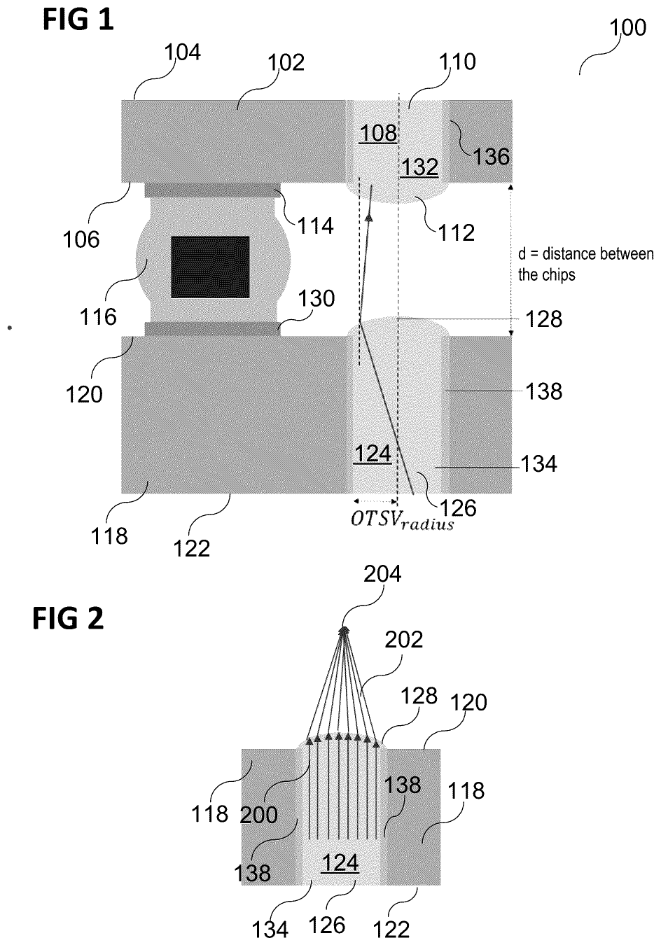

FIG. 1, a section of a semiconductor assembly according to various aspects of the present disclosure;

FIG. 2, a section of a semiconductor assembly according to various aspects of the present disclosure;

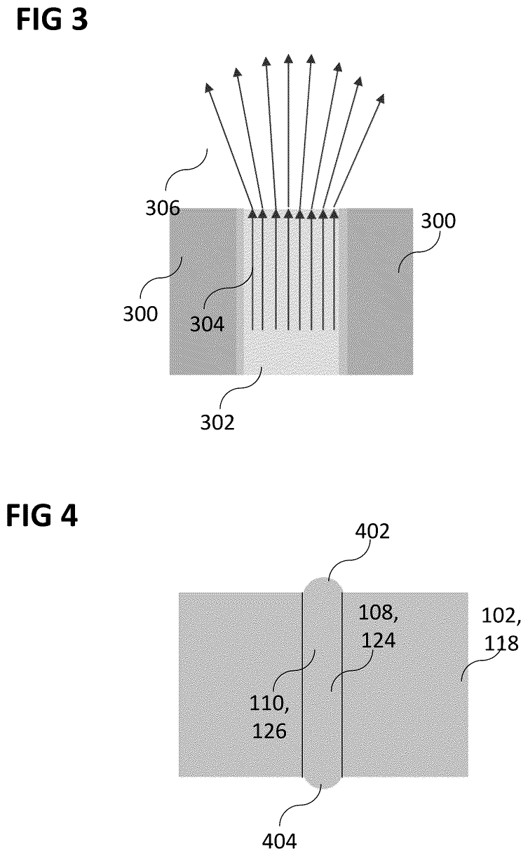

FIG. 3, a section of a semiconductor assembly;

FIG. 4, a section of a semiconductor assembly according to various aspects of the present disclosure;

FIG. 5, a section of a semiconductor assembly according to various aspects of the present disclosure;

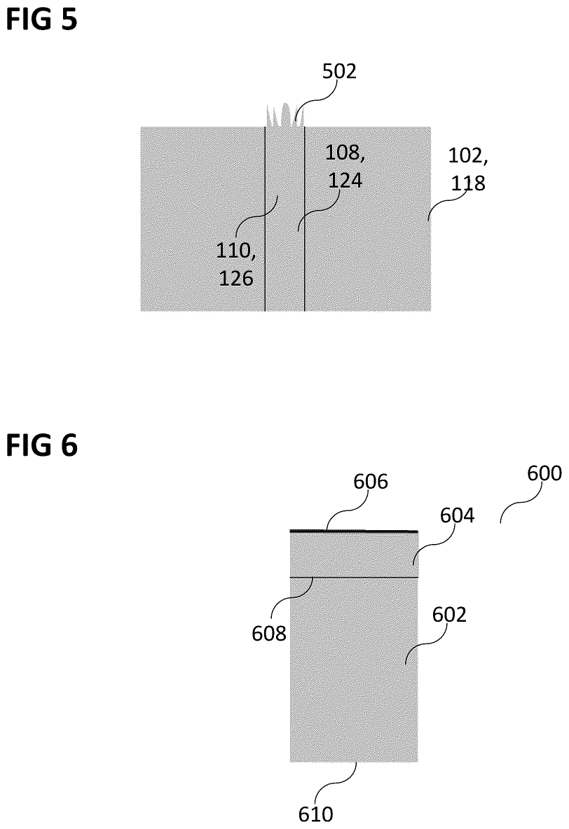

FIG. 6, a section of a semiconductor assembly according to various aspects of the present disclosure;

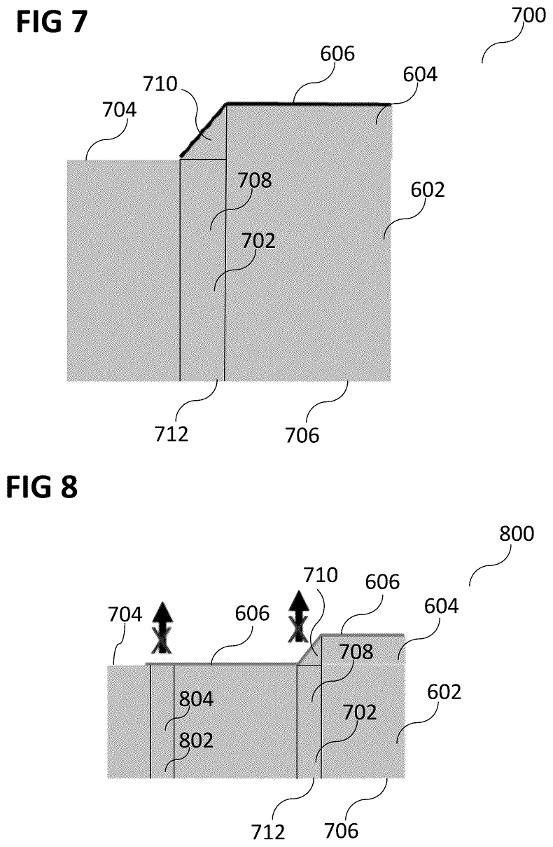

FIG. 7, a section of a semiconductor assembly according to various aspects of the present disclosure;

FIG. 8, a section of a semiconductor assembly according to various aspects of the present disclosure;

FIG. 9, a section of a semiconductor assembly according to various aspects of the present disclosure;

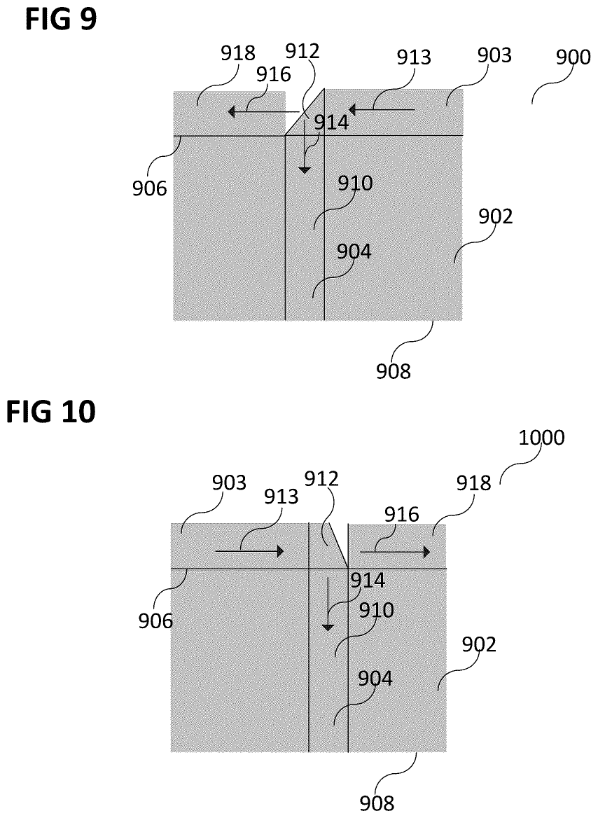

FIG. 10, a section of a semiconductor assembly according to various aspects of the present disclosure;

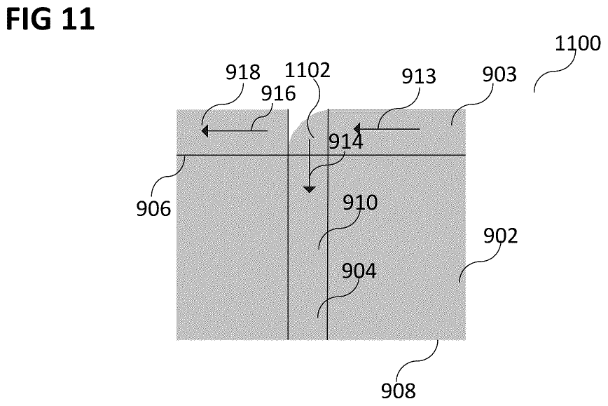

FIG. 11, a section of a semiconductor assembly according to various aspects of the present disclosure;

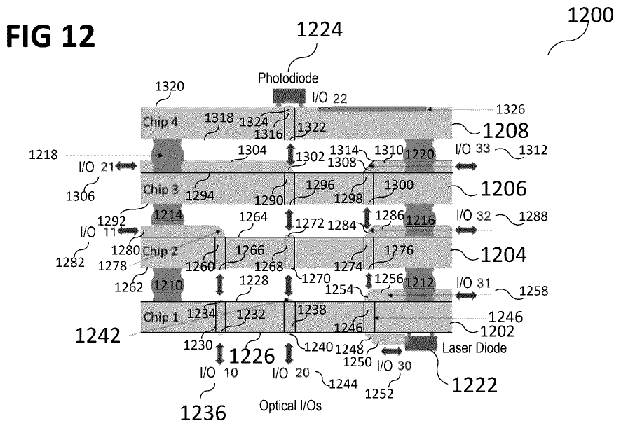

FIG. 12, a semiconductor assembly according to various aspects of the present disclosure; and

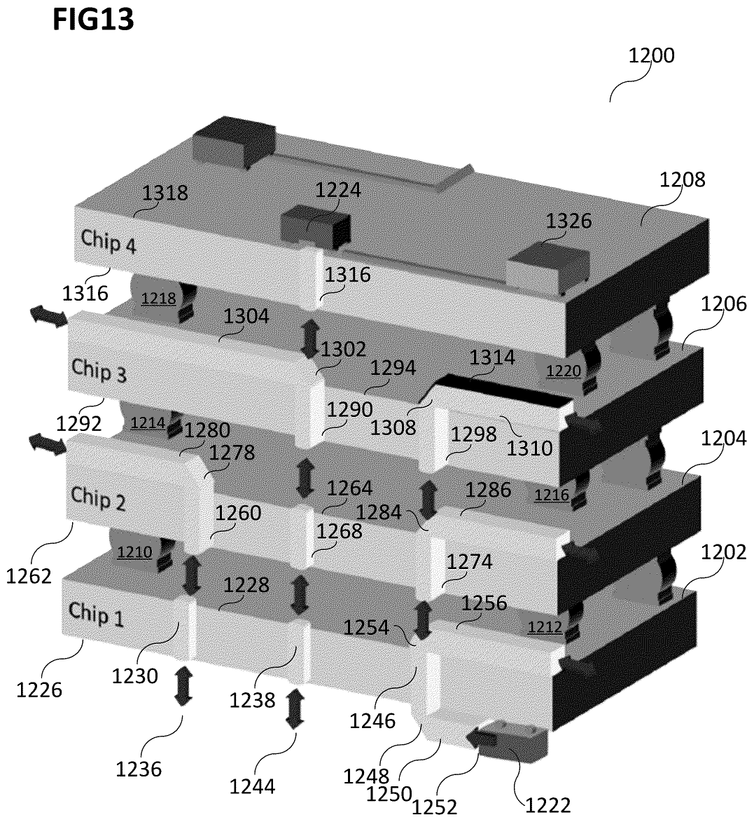

FIG. 13, a semiconductor assembly according to various aspects of the present disclosure.

In the following detailed description, reference is made to the accompanying drawings which form part thereof and in which are shown, by way of illustration, specific embodiments in which the invention may be practiced. In this regard, directional terminology such as “top”, “bottom”, “front”, “rear”, “forward”, “rearward”, etc. is used with reference to the orientation of the figure(s) described. Since components of embodiments may be positioned in a number of different orientations, the directional terminology is for illustrative purposes and is not limiting in any way. It is understood that other embodiments may be used and structural or logical changes may be made without departing from the scope of protection of the present invention. It is to be understood that the features of the various exemplary embodiments described herein may be combined with each other, unless specifically indicated otherwise. The following detailed description is therefore not to be construed in a limiting sense, and the scope of protection of the present invention is defined by the appended claims.

In the context of this description, the terms “connected”, “connected” and “coupled” are used to describe both a direct and an indirect connection, a direct or indirect connection and a direct or indirect coupling. In the figures, identical or similar elements are provided with identical reference signs where appropriate.

Various aspects of the present disclosure provide a solution for purely optical intra-chip communication and/or inter-chip communication without significant electro-optical conversion or opto-electrical conversion.

FIG. 1 shows a detail of a semiconductor assembly 100 according to various aspects of the present disclosure.

The semiconductor assembly 100 may comprise a first semiconductor substrate 102 having a front surface 104 and a back surface 106 opposite the front surface. The first semiconductor substrate 102 comprises a first through-hole 108 extending from the front side 104 of the first semiconductor substrate 102 to the back side 106 of the first semiconductor substrate 102. A first optical waveguide structure (for example, a first optical waveguide) 110 is formed in the first through-hole 108 for guiding optical waves between the front surface 104 of the first semiconductor substrate 102 and the back surface 106 of the first semiconductor substrate 102. Thus, illustratively, a first optical through-silicon via (e.g., a first OTSV—optical through-silicon via) is formed in the first semiconductor substrate 102.

The semiconductor assembly 100 may further comprise a second semiconductor substrate 118 having a front surface 120 and a back surface 122 opposite the front surface 120. The second semiconductor substrate 118 comprises a second through-hole 124 extending from the front surface 120 of the second semiconductor substrate 118 to the back surface 122 of the second semiconductor substrate 118. A second optical waveguide structure (for example, a second optical waveguide) 126 is formed in the second through-hole 124 for guiding optical waves between the front surface 120 of the second semiconductor substrate 118 and the back surface 122 of the second semiconductor substrate 118. The first semiconductor substrate 102 and the second semiconductor substrate 118 are arranged at a distance “d” from each other and (relative) to each other such that optical waves coupled out from the first optical waveguide structure 110 are coupled into the second optical waveguide structure 126 and vice versa. Thus, illustratively, a second optical through-silicon via (e.g., a second OTSV—optical through-silicon via) is formed in the second semiconductor substrate 118, for example.

The semiconductor assembly 100 may further comprise at least one first optical lens 112 or at least one first optical meta-structure configured to refract the optical waves coupled out from the first optical waveguide structure 110 in the direction of the second optical waveguide structure 126, and/or at least one second optical lens 128 or at least one second optical meta-structure configured to refract the optical waves coupled out from the first optical waveguide structure 110 in the direction of the second optical waveguide structure 126.

In the context of this description, a meta-structure is to be understood as any structure that implements beam shaping (also referred to as “beam forming”) of the respective emitted/received beams in the desired manner.

The first semiconductor substrate 102 and/or the second semiconductor substrate 118 may comprise or consist of semiconductor material. The semiconductor material may be IV semiconductor material (for example, silicon) or a composite semiconductor material, such as a binary composite semiconductor material, e.g., an IV-VI composite semiconductor material (e.g., silicon-germanium). The first semiconductor substrate may be a silicon germanium (SiGe) or a II-VI compound semiconductor material or a III-V-compound semiconductor material (e.g. GaN or InP), or a ternary compound semiconductor material (e.g. GaInP).

The first semiconductor substrate 102 and/or the second semiconductor substrate 118 may consist exclusively of semiconductor material and may be configured as an interposer, for example. The first semiconductor substrate 102 and/or the second semiconductor substrate 118 may comprise monolithically integrated components. The first semiconductor substrate 102 and/or the second semiconductor substrate 118 can be configured as a semiconductor chip, for example as a logic semiconductor chip.

The first semiconductor substrate 102 and the second semiconductor substrate 118 may be mechanically connected to each other, for example by means of solder connections, for example by means of one or more solder balls 116, for example by means of one or more micro solder balls 116. The first semiconductor substrate 102 and/or the second semiconductor substrate 118 may comprise solder pads 114, 130 on which the solder balls 116 are soldered.

The first optical waveguide structure 110 fills the first through-hole 108 and the second optical waveguide structure 126 fills the second through-hole 124. The first optical waveguide structure 110 and/or the second optical waveguide structure 126 may include a waveguide core 132, 134. The waveguide core 132, 134 may comprise or consist of optically transparent material (for the wavelength(s) of the optical waves to be transmitted). The waveguide core 132, 134 of the first optical waveguide structure 110 and/or the second optical waveguide structure 126 may be formed of a first polymeric material, alternatively any material, for example semiconductor material, which allows guiding of optical waves with sufficiently low attenuation (e.g., silicon (Si), silicon oxide (SiO₂), silicon nitride (Si₃N₄), indium phosphide (InP), lithium niobate (LiNbO₃), and the like).

The first optical waveguide structure 110 and/or the second optical waveguide structure 126 may comprise a waveguide cladding 136, 138 (e.g., SiO₂) disposed between the waveguide core 132, 134 and the inner wall of the first through-hole 108 and/or the second through-hole 124. The waveguide cladding 136, 138 and the respective waveguide core 132, 134 are configured relative to each other such that an optical shaft of a desired wavelength is totally reflected in the first optical waveguide structure 110 and/or the second optical waveguide structure 126.

The first optical lens 112 (or first optical meta-structure) may be monolithically integrated with the first optical waveguide structure 110. The second optical lens 128 (or the second optical meta-structure) may be monolithically integrated with the second optical waveguide structure 126. However, the first optical lens 112 (or the first optical meta-structure) and/or the second optical lens 128 (or the second optical meta-structure) may also be applied separately to the respective optical waveguide structure 110, 126, for example printed thereon, for example in a subsequent manufacturing process independent of the forming of the respective optical waveguide structure 110, 126.

The first optical lens 112 (or the first optical meta-structure) and/or the second optical lens 128 (or the second optical meta-structure) may be formed of a (second) polymer material.

The first polymeric material and the second polymeric material may be the same polymeric material.

The first optical lens 112 and/or the second optical lens 128 may be configured as spherical lens(es). Alternatively, the first optical lens 112 and/or the second optical lens 128 may be configured as aspherical lens(es).

In the event that the respective optical waveguide structure 110, 126 is configured as a single mode waveguide structure 110, 126, the first through-hole 108 and/or the second through-hole 124 may have a diameter in a region from about 4 μm to about 12 μm, for example in a region from about 6 μm to about 10 μm.

In this case, the first optical lens 112 and/or the second optical lens 128 may have a diameter in a region from about 2 μm to about 14 μm, for example, in a region from about 4 μm to about 10 μm.

In the event that the respective optical waveguide structure 110, 126 is configured as a multi-mode waveguide structure 110, 126, the first through-hole 108 and/or the second through-hole 124 may have a diameter in a region from about 20 μm to about 200 μm, for example in a region from about 40 μm to about 100 μm.

In this case, the first optical lens 112 and/or the second optical lens 128 may have a diameter in a region from about 10 μm to about 300 μm, for example in a region from about 30 μm to about 120 μm.

In FIG. 1, the semiconductor assembly 100 is shown with two semiconductor substrates 102, 118. However, in various aspects of the present disclosure, more than two semiconductor substrates may be provided, for example, three, four, five, more than five, ten, more than ten, twenty, more than twenty, thirty, or even more semiconductor substrates may be provided in the 3D chip stack. One or more of these semiconductor substrates may be configured as interposers and/or one or more of these semiconductor substrates may be configured as semiconductor chips.

In various aspects of the present disclosure, the semiconductor assembly may further comprise a third semiconductor substrate having a front side and a back side opposite the front side. The third semiconductor substrate may comprise a third through-hole extending from the front side of the third semiconductor substrate to the back side of the third semiconductor substrate. A third optical waveguide structure (for example, a third optical waveguide) is formed in the third through-hole for guiding optical waves between the front surface of the third semiconductor substrate and the back surface of the third semiconductor substrate. The third semiconductor substrate is disposed on the side of the first semiconductor substrate that is distal from the second semiconductor substrate. The first semiconductor substrate and the third semiconductor substrate are arranged at a distance from each other and (relative) to each other in such a way that optical waves coupled out from the first optical waveguide structure are coupled into the third optical waveguide structure. The third semiconductor substrate may further comprise a third optical lens (or a third optical meta-structure) configured to refract the optical waves coupled out from the first optical waveguide structure 110 in the direction of the third optical waveguide structure. The third optical lens (or the third optical meta-structure) may be monolithically integrated with the third optical waveguide structure.

If all semiconductor substrates of the semiconductor assembly comprise such optical waveguide structures in one or more through-holes with a respective optical lens (or with a respective optical meta-structure), a very energy efficient and fast optical coupling between the semiconductor substrates of the semiconductor assembly (for example a 3D chip stack) is enabled.

It should be noted that the direction of propagation of the light through the semiconductor substrates can also be reversed compared to the direction of propagation as described above in connection with FIG. 1 for the sake of simplicity.

FIG. 2 shows an enlarged portion of the semiconductor assembly 100 according to various aspects of the present disclosure, namely a portion of the second semiconductor substrate 118 having the second through-hole 124 in which the second waveguide structure 126 is formed. Furthermore, the second optical lens 128 is shown. As an example, FIG. 2 shows parallel optical waves propagating in the second waveguide structure 126 in the form of parallel light beams 200, which are refracted into refracted light beams 202 when exiting the second optical lens 128 in the direction of a focal point 204 (in the 3D chip stack, such as of the semiconductor assembly 100, as light beams 202 refracted from the second semiconductor substrate 118 in the direction of the first semiconductor substrate 102, more precisely in the direction of the first waveguide structure 110, for example in the direction of the waveguide core (e.g., the central axis of the waveguide core) of the first waveguide structure 110).

For comparison, FIG. 3 shows a waveguide structure 302 in a semiconductor substrate 300 without an optical lens. In this case, parallel optical waves propagating in the waveguide structure 302 in the form of parallel light beams 304 are also refracted as they exit the waveguide structure 302, but to form a widening light beam 306.

FIG. 4 shows a simplified representation of the first waveguide structure 110 or the second waveguide structure 126, but where an optical lens 402, 404 (or an optical meta-structure in each case) is provided at each end of the through-hole (first through-hole 108 or second through-hole 124), which is optionally monolithically integrated with the waveguide core of the respective waveguide structure 110, 126.

FIG. 5 shows a simplified representation of the first waveguide structure 110 or the second waveguide structure 126, but where an optical meta-structure 502 is provided at one end of the through-hole (first through-hole 108 or second through-hole 124). The optical meta-structure 502 may optionally be monolithically integrated with the waveguide core of the respective waveguide structure 110, 126.

In various aspects of the present disclosure, the semiconductor assembly 100 may be encapsulated with encapsulant material, such as molding compound, to form a semiconductor package. Alternatively, any suitable polymer material may be used as the encapsulating material, for example to reduce optical transmission or refractive power losses in the vicinity of the semiconductor assembly 100.

FIG. 6 illustrates a semiconductor assembly 600 according to various aspects of the present disclosure.

The semiconductor assembly 600 may comprise a semiconductor substrate 602 having an optical waveguide structure 604 disposed thereon, and a shielding structure 606 disposed on the optical waveguide structure 604 opposite the semiconductor substrate 602, the shielding structure 606 comprising metal and configured to shield energy emanating from the optical waveguide structure 604, wherein the shielding structure 606 is in physical contact with the optical waveguide structure 604.

The semiconductor substrate 602 may comprise or consist of semiconductor material. The semiconductor material may be IV semiconductor material (for example, silicon) or a compound semiconductor material, for example, binary compound semiconductor material, for example, a IV-IV compound semiconductor material (for example, silicon-germanium (SiGe) or a II-VI compound semiconductor material or a III-V compound semiconductor material (for example, GaN or InP), or a ternary compound semiconductor material (for example, GaInP).

The laterally extending optical waveguide structure 604 may be configured as an optical redistribution layer 604 and may be disposed on a surface (for example, a front surface 608 of the semiconductor substrate 602 or a back surface 610 of the semiconductor substrate 602) 608, 610 of the semiconductor substrate 602.

The laterally extending optical waveguide structure 604 may be configured like the first optical waveguide structure 110 or like the second optical waveguide structure 126 as described above with reference to FIG. 1.

The shielding structure 606 may comprise metal or be formed of a metal. The metal may have a layer thickness in a region from about 50 nm to about 600 nm, for example in a region from about 150 nm to about 350 nm, for example a layer thickness of about 300 nm. In principle, any metal may be used if the layer thickness is sufficient to ensure that there is a sufficiently low transmissivity for the optical waves guided by the optical waveguide structure 604, for example a transmissivity in a region of at most about 5% for optical waves in a wavelength range of interest, for example a transmissivity in a region of at most about 4%, for example a transmissivity in a region of at most about 3%, for example a transmissivity in a region of at most about 2%, for example a transmissivity in a region of at most about 1%.

The metal may comprise one or more metals, for example a metal alloy of several metals.

The metal may be a metal from a group of metals comprising or consisting of:
aluminum (Al); and/or
silver (Ag); and/or
gold (Au); and/or
an alloy of one or more of the above metals.

The semiconductor substrate 602 may be configured as a semiconductor chip, such as a logic semiconductor chip.

By means of the shielding structure 606, it is thus achieved that no energy (and thus, for example, no data) can undesirably leak out of the optical waveguide structure 604 through the shielding structure 606, for example in the context of data transmission or energy transmission.

In various aspects of the present disclosure, the semiconductor assembly 600 according to FIG. 6 may be encapsulated with encapsulating material, for example molding compound, and form a semiconductor package therewith.

The semiconductor assembly 600 according to FIG. 6 may be combined with other optical interconnection elements, such as one or more waveguide structures formed in a through-hole for inter-semiconductor substrate coupling (e.g., inter-chip coupling) or with deflection coupling elements, as will be discussed in more detail below.

For example, FIG. 7 shows a semiconductor assembly 700 in which a through-hole 702 is additionally provided in the semiconductor substrate 602, which extends from a front surface 704 of the semiconductor substrate 602 to the back surface 706 of the semiconductor substrate 602 and in which a vertically extending optical waveguide structure 708 is formed. The vertically extending optical waveguide structure 708 may be configured like the first optical waveguide structure 110 or like the second optical waveguide structure 126, as described above with reference to FIG. 1.

Further, an optical coupling element 710 may be provided to optically couple the optical waveguide structure 604 to the vertically extending optical waveguide structure 708 (also referred to herein as the through-hole optical waveguide structure 708). The optical coupling element 710 may comprise an angled optical connection 710.

The shielding structure 606 may extend at least partially on the angled optical connection 710 for shielding energy exiting the angled optical connection 710.

In the context of the description, energy exiting a waveguide structure means any type of energy (for example, in wave form) that exits a waveguide structure, for example, as a leakage or non-totally reflected shaft.

In various aspects of the present disclosure, the semiconductor assembly 700 according to FIG. 7 may be encapsulated with encapsulating material, for example molding compound, and form a semiconductor package therewith.

Optionally, an optical lens (or an optical meta-structure) may be disposed at the end of the through-hole optical waveguide structure 708 on the backside 706 of the semiconductor substrate 602, for example an optical lens (or an optical meta-structure) as described above.

By means of the shielding structure 606, it is additionally achieved that no energy (and thus, for example, no data) can escape undesirably through the shielding structure 606, for example in the context of data transmission or energy transmission from the angled connection 710.

FIG. 8 shows a semiconductor assembly 800 according to various aspects of the present disclosure.

In addition to the semiconductor assembly 700 of FIG. 7, the semiconductor assembly 800 comprises an additional through-hole 802 in which an additional waveguide structure 804 is configured to be formed. The additional waveguide structure 804 may also be covered at its end on the front side 704 of the semiconductor substrate 602 with the shielding structure 606 (for example a metal layer, also referred to as a metal filter).

By means of the shielding structure 606, it is thus additionally achieved that no energy (and thus, for example, no data) can escape undesirably through the shielding structure 606 from the end of the additional waveguide structure 804 on the front side 704 of the semiconductor substrate 602, for example in the context of data transmission or energy transmission.

FIG. 9 illustrates a semiconductor assembly 900 according to various aspects of the present disclosure.

The semiconductor assembly 900 may comprise a semiconductor substrate 902 having a laterally extending optical waveguide structure 903 disposed thereon. The semiconductor substrate 900 comprises a through-hole 904 extending from a front side 906 of the semiconductor substrate 902 to a back side 908 of the semiconductor substrate 902. A through-hole optical waveguide structure 910 is formed in the through-hole 904 for guiding optical waves between the front side 906 of the semiconductor substrate 902 and the back side 908 of the semiconductor substrate 902. The semiconductor assembly 900 further comprises an angled optical connection 912 for optically connecting the laterally extending optical waveguide structure 903 to the through-hole optical waveguide structure 910. The angled optical connection 912 is configured as an optical beam splitter for dividing optical waves guided in the laterally extending optical waveguide structure 903 in the direction of the angled optical connection 912 (symbolized by means of a first arrow 913) into a first part (symbolized by means of a second arrow 914) and a second part (symbolized by means of a third arrow 916). The first portion 914 of the optical waves 913 is optically coupled into the through-hole waveguide structure 910. Further, the semiconductor assembly 900 has an additional laterally extending optical waveguide structure 918 disposed on the front surface 906 of the semiconductor substrate 902, which is optically coupled to the angled optical connection 912 such that the second portion 916 of the optical waves 913 is optically coupled into the additional laterally extending optical waveguide structure 918.

Thus, illustratively, the angled optical connection 912 has the function of an optical beam splitter.

The angled optical connection 912 represents an example of an optical coupling element.

The angled optical connection may provide a deflection angle in a region from about 1° to about 89°, for example, a deflection angle in a region from about 26° to about 74°, for example, a deflection angle in a region from about 35° to about 54°, for example, a deflection angle of about 45°.

The first portion 914 of the optical waves 913 may comprise a portion of the energy of the optical waves 913 in a region from about 1% to about 99%. Accordingly, the second portion 916 of the optical waves 913 may also comprise a portion of the energy of the optical waves 913 in a region of from about 1% to about 99%.

The semiconductor substrate 902 may comprise or consist of semiconductor material. The semiconductor material may be IV semiconductor material (for example, silicon) or a composite semiconductor material, such as a binary composite semiconductor material, e.g., an IV-IV composite semiconductor material (e.g., a silicon germanium (SiGe) or a II-VI compound semiconductor material or a III-V compound semiconductor material (e.g. GaN or InP), or a ternary compound semiconductor material (e.g. GaInP).

The laterally extending optical waveguide structure 903 and/or the additional laterally extending optical waveguide structure 918 may be configured as an optical redistribution layer 903, 918 and arranged on a surface (for example, the front surface 906 or the back surface 908 of the semiconductor substrate 902) of the semiconductor substrate 902.

The laterally extending optical waveguide structure 903 and/or the optical via waveguide structure 910 and/or the additional laterally extending optical waveguide structure 918 may be configured like the first optical waveguide structure 110 or like the second optical waveguide structure 126, as described above under FIG. 1.

The semiconductor substrate 902 may be configured as a semiconductor chip, such as a logic semiconductor chip.

In various aspects of the present disclosure, the semiconductor assembly 900 according to FIG. 9 may be encapsulated with encapsulating material, for example molding compound, and form a semiconductor package therewith.

FIG. 10 shows a semiconductor assembly 1000 according to various aspects of the present disclosure. The semiconductor assembly 1000 according to FIG. 10 is similar to the semiconductor assembly 900 according to FIG. 9, which is why only the differences between the semiconductor assembly 1000 according to FIG. 10 and the semiconductor assembly 900 according to FIG. 9 are shown below.

In comparison with the semiconductor assembly 900 according to FIG. 9, on the one hand the deflection angle of the angled optical connection 912 is steeper, namely in a region of approximately 54° to approximately 74°. Furthermore, the optical waves 913 in FIG. 10 extend from left to right and the angled optical connection 912 is arranged to the right of the laterally extending optical waveguide structure 903. The additional laterally extending optical waveguide structure 918 is also arranged to the right of the laterally extending optical waveguide structure 903 and the angled optical connection 912.

FIG. 11 illustrates a semiconductor assembly 1100 according to various aspects of the present disclosure. The semiconductor assembly 1100 according to FIG. 11 is similar to the semiconductor assembly 900 according to FIG. 9, and therefore only the differences of the semiconductor assembly 1100 according to FIG. 11 compared to the semiconductor assembly 900 according to FIG. 9 are shown below.

In comparison to the semiconductor assembly 900 according to FIG. 9, the angled optical connection 1102 of the semiconductor assembly 1100 according to FIG. 11 is configured to be in the form of a continuously curved optical connection 1102.

Thus, the angled optical connection 1102 of the semiconductor assembly 1100 according to FIG. 11 illustratively represents a continuously curved optical coupling element.

FIG. 12 and FIG. 13 show a semiconductor assembly 1200 comprising the various optical coupling elements described above.

The semiconductor assembly 1200 comprises, by way of example, four semiconductor substrates 1202, 1204, 1206, 1208, which in this example are all formed as logic semiconductor chips 1202, 1204, 1206, 1208, namely a first logic semiconductor chip 1202, a second logic semiconductor chip 1204, a third logic semiconductor chip 1206 and a fourth logic semiconductor chip 1208. The logic semiconductor chips 1202, 1204, 1206, 1208 are arranged one above the other and form a three-dimensional chip stack. The logic semiconductor chips 1202, 1204, 1206, 1208 are mechanically and electrically connected to each other by means of solder connections, in this example by means of solder balls (for example microbumps) 1210, 1212, 1214, 1216, 1218, 1220, which are soldered to solder pads not shown in the figure.

Furthermore, a light source 1222, for example configured as a laser diode 1222, is provided. The light source 1222 is configured to generate light, for example laser light, which is coupled into waveguide structures of the semiconductor assembly 1200, which will be explained in more detail below.

Furthermore, a photosensitive sensor 1224, for example configured as a photodiode 1224, is provided. The photosensitive sensor 1224 is configured to capture light, for example laser light, which is coupled out of waveguide structures of the semiconductor assembly 1200. It should be noted that several, in principle any number, of light sources 1222 and/or photosensitive sensors 1224 may be provided in the semiconductor assembly 1200. It is further possible that light is provided from a light source external to the semiconductor assembly (for example, by means of an optical fiber cable), wherein the light is coupled directly into a light conducting structure (for example, into one or more of the waveguide structures of the semiconductor assembly 1200), for example. Furthermore, it is possible to couple light out of a light-conducting structure (for example, one or more of the waveguide structures of the semiconductor assembly 1200) to a semiconductor assembly-external light detector (for example, by means of an optical fiber cable).

In this example, the first logic semiconductor chip 1202 comprises the following optical coupling elements, generally the following optical components, which may be formed in the first logic semiconductor chip 1202:
a first through-hole optical waveguide structure 1230 (for example, a first optical waveguide 1230) extending from a rear side 1226 of the first logic semiconductor chip 1202 through the first logic semiconductor chip 1202 to a front side 1228 of the first logic semiconductor chip 1202, wherein optical lenses 1232, 1234 (or optical meta-structures) (for example, optical lenses (or optical meta-structures) as described above) are optionally attached, for example monolithically integrated, to one or both ends of the first through-hole optical waveguide structure 1230; a lower end of the first through-hole optical waveguide structure 1230 having an optional first optical lens 1232 at the rear side 1226 of the first logic semiconductor chip 1202 forms a first optical input/output interface (I/O 10) 1234 configured to couple and/or decouple optical waves into or out of the semiconductor assembly 1200;
a second through-hole optical waveguide structure 1238 (for example, a second optical waveguide 1238) extending from the rear side 1226 of the first logic semiconductor chip 1202 through the first logic semiconductor chip 1202 to the front side 1228 of the first logic semiconductor chip 1202, wherein optical lenses 1240, 1242 (or optical meta-structures) (for example, optical lenses (or optical meta-structures) as described above) are optionally attached, for example monolithically integrated, to one or both ends of the second through-hole optical waveguide structure 1238; a lower end of the second through-hole optical waveguide structure 1238 having an optional first optical lens 1240 (or having an optional first optical meta-structure) at the backside 1226 of the first logic semiconductor chip 1202 forms a second optical input/output interface (I/O 20) 1244 configured to couple and/or decouple optical waves into or out of the semiconductor assembly 1200;
a third through-hole optical waveguide structure 1246 (for example, a third optical waveguide 1246) extending from the rear side 1226 of the first logic semiconductor chip 1202 through the first logic semiconductor chip 1202 to the front side 1228 of the first logic semiconductor chip 1202;
a first angled optical connection 1248;
a first lateral optical waveguide structure 1250 disposed on the bottom surface 1226 of the first logic semiconductor chip 1202 and extending on and along the bottom surface of the first logic semiconductor chip 1202;
a first end of the first angled optical connection 1248 is optically connected (e.g., directly) to a first end of the third through-hole optical waveguide structure 1246; and a second end of the first angled optical connection 1248 is optically connected (e.g., directly) to a first end of the first lateral optical waveguide structure 1250;
a second end of the first lateral optical waveguide structure 1250 forms a third optical input/output interface (I/O 30) 1252 configured to couple and/or decouple optical waves into or out of the semiconductor assembly 1200 and may be optically connected (e.g. directly) to the light source 1222
a second angled optical connection 1254 configured, for example, as a continuously curved coupling element and as a beam splitter;
a second lateral optical waveguide structure 1256 disposed on the top surface 1228 of the first logic semiconductor chip 1202 and extending on and along the top surface of the first logic semiconductor chip 1202;
a first end of the second angled optical connection 1254 is optically connected to a second end of the third through-hole optical waveguide structure 1246 (e.g., directly), and a second end of the second angled optical connection 1254 is optically connected to a first end of the second lateral optical waveguide structure 1256 (e.g., directly);
a second end of the second lateral optical waveguide structure 1256 forms a fourth optical input/output interface (I/O 31) 1258 configured to couple and/or decouple optical waves into or out of the semiconductor assembly 1200.

In this example, the second logic semiconductor chip 1204 comprises the following optical coupling elements, generally the following optical components:
a fourth through-hole optical waveguide structure 1260 (for example, a fourth optical waveguide 1260) extending from a rear side 1262 of the second logic semiconductor chip 1204 through the second logic semiconductor chip 1204 to a front side 1264 of the second logic semiconductor chip 1204, wherein an optical lens 1266 (or an optical meta-structure) (for example, an optical lens (or an optical meta-structure) as described above) is optionally attached, for example monolithically integrated, to a first end of the fourth through-hole optical waveguide structure 1260; the optical lens 1266 (or optical meta-structure) is positioned relative to the optical lens 1234 (or optical meta-structure) of the first through-hole optical waveguide structure 1230 such that optical signals can be exchanged between the first through-hole optical waveguide structure 1230 and the fourth through-hole optical waveguide structure 1260;
a fifth through-hole optical waveguide structure 1268 (for example, a fifth optical waveguide 1268) extending from the rear side 1262 of the second logic semiconductor chip 1204 through the second logic semiconductor chip 1204 to the front side 1264 of the second logic semiconductor chip 1204, wherein optical lenses 1270, 1272 (or optical meta-structures) (for example, optical lenses (or optical meta-structures) as described above) are optionally attached, for example monolithically integrated, to one or both ends of the fifth through-hole optical waveguide structure 1268; a lower end of the fifth through-hole optical waveguide structure 1268 having an optional first optical lens 1270 (or having an optional first optical meta-structure) on the backside 1262 of the second logic semiconductor chip 1204 is positioned relative to the optical lens 1242 (or optical meta-structure) of the second through-hole optical waveguide structure 1238 such that optical signals can be exchanged between the fifth through-hole optical waveguide structure 1268 and the second through-hole optical waveguide structure 1238;
a sixth through-hole optical waveguide structure 1274 (for example, a sixth optical waveguide 1274) extending from the rear side 1262 of the second logic semiconductor chip 1204 through the second logic semiconductor chip 1204 to the front side 1264 of the second logic semiconductor chip 1204,
wherein an optical lens 1276 (or an optical meta-structure) (for example, an optical lens (or an optical meta-structure) as described above) is optionally attached, for example monolithically integrated, to a first end of the sixth through-hole optical waveguide structure 1274; the optical lens 1276 (or optical meta-structure) is arranged relative to the second angled optical connection 1254 such that optical signals can be exchanged between the sixth through-hole optical waveguide structure 1274 and the third through-hole optical waveguide structure 1246;
a third angled optical connection 1278 configured, for example, as a continuously curved coupling element and as a beam splitter;
a third lateral optical waveguide structure 1280 disposed on the top surface 1264 of the second logic semiconductor chip 1204 and extending on and along the top surface of the second logic semiconductor chip 1204;
a first end of the third angled optical connection 1278 is optically connected to a second end of the fourth through-hole optical waveguide structure 1260 (e.g., directly), and a second end of the third angled optical connection 1278 is optically connected to a first end of the third lateral optical waveguide structure 1280 (e.g., directly);
a second end of the third lateral optical waveguide structure 1278 forms a fifth optical input/output interface (I/O 11) 1282 configured to couple and/or decouple optical waves into or out of the semiconductor assembly 1200;
a fourth angled optical connection 1284;
a fourth lateral optical waveguide structure 1286 disposed on the top surface 1264 of the second logic semiconductor chip 1204 and extending on and along the top surface of the second logic semiconductor chip 1204;
a first end of the fourth angled optical connection 1284 is optically connected to a second end of the sixth through-hole optical waveguide structure 1274 (e.g., directly), and a second end of the fourth angled optical connection 1284 is optically connected to a first end of the fourth lateral optical waveguide structure 1286 (e.g., directly);
a second end of the fourth lateral optical waveguide structure 1286 forms a sixth optical input/output interface (I/O 32) 1288 configured to couple and/or decouple optical waves into or out of the semiconductor assembly 1200.

In this example, the third logic semiconductor chip 1206 comprises the following optical coupling elements, generally the following optical components:
a seventh through-hole optical waveguide structure 1290 (for example, a seventh optical waveguide 1290) extending from a rear side 1292 of the third logic semiconductor chip 1206 through the third logic semiconductor chip 1206 to a front side 1294 of the third logic semiconductor chip 1206, wherein an optical lens 1296 (or an optical meta-structure) (for example, an optical lens (or an optical meta-structure) as described above) is optionally attached, for example monolithically integrated, to a first end of the seventh through-hole optical waveguide structure 1290; the optical lens 1296 (or optical meta-structure) is positioned relative to the optical lens 1272 (or optical meta-structure) of the fifth through-hole optical waveguide structure 1268 such that optical signals can be exchanged between the seventh through-hole optical waveguide structure 1290 and the fifth through-hole optical waveguide structure 1268;
an eighth through-hole optical waveguide structure 1298 (for example, an eighth optical waveguide 1298) extending from the rear side 1292 of the third logic semiconductor chip 1206 through the third logic Semiconductor chip 1206 to the front side 1294 of the third logic semiconductor chip 1206, wherein an optical lens 1300 (or an optical meta-structure) (for example, an optical lens (or an optical meta-structure) as described above) is optionally attached, for example monolithically integrated, to a first end of the eighth through-hole optical waveguide structure 1298; the optical lens 1300 (or optical meta-structure) is arranged relative to the fourth angled optical connection 1284 such that optical signals can be exchanged between the eighth through-hole optical waveguide structure 1298 and the fourth angled optical connection 1284;
a fifth angled optical connection 1302 configured as a beam splitter;
a fifth lateral optical waveguide structure 1304 disposed on the top surface 1294 of the third logic semiconductor chip 1206 and extending on and along the top surface of the third logic semiconductor chip 1206;
a first end of the fifth angled optical connection 1302 is optically connected (e.g., directly) to a second end of the seventh through-hole optical waveguide structure 1290; and a second end of the fifth angled optical connection 1302 is optically connected (e.g., directly) to a first end of the fifth lateral optical waveguide structure 1304;
a second end of the fifth lateral optical waveguide structure 1304 forms a seventh optical input/output interface (I/O 21) 1306 configured to couple and/or decouple optical waves into or out of the semiconductor assembly 1200;
a sixth angled optical connection 1308;
a sixth lateral optical waveguide structure 1310 disposed on the top surface 1294 of the third logic semiconductor chip 1206 and extending on and along the top surface of the third logic semiconductor chip 1206;
a first end of the sixth angled optical connection 1308 is optically connected to a second end of the eighth through-hole optical waveguide structure 1298 (e.g., directly) and a second end of the sixth angled optical connection 1308 is optically connected to a first end of the sixth lateral optical waveguide structure 1310 (e.g., directly);
a second end of the sixth lateral optical waveguide structure 1310 forms an eighth optical input/output interface (I/O 33) 1312 configured to couple and/or decouple optical waves into or out of the semiconductor assembly 1200;
a shielding structure 1314 is provided on the exposed surface of the sixth angled optical connection 1308 and on the exposed surface of the sixth lateral optical waveguide structure 1310, for example a shielding structure as described above.

In this example, the fourth logic semiconductor chip 1208 has the following optical coupling elements, generally the following optical components:
a ninth through-hole optical waveguide structure 1316 (for example, a ninth optical waveguide 1316) extending from a rear side 1318 of the fourth logic semiconductor chip 1208 through the fourth logic semiconductor chip 1208 to a front side 1320 of the fourth logic semiconductor chip 1208, wherein optical lenses 1322, 1324 (or optical meta-structures) (for example, optical lenses (or optical meta-structures) as described above) are optionally attached, for example monolithically integrated, to one or both ends of the ninth through-hole optical waveguide structure 1316; the optical lens 1322 (or optical meta-structure) is arranged relative to the fifth angled optical connection 1302 such that optical signals can be exchanged between the ninth through-hole optical waveguide structure 1316 and the fifth angled optical connection 1302;
a second end of the ninth through-hole optical waveguide structure 1316 having an optional optical lens 1324 (or having an optical meta-structure) at the front side 1320 of the fourth logic semiconductor chip 1208 is arranged relative to the photosensitive sensor 1224, such as the photodiode 1224, such that the photosensitive sensor 1224 can capture optical signals from the ninth through-hole optical waveguide structure 1316; the photosensitive sensor 1224 is electrically connected to an electrical connection 1326 such that an electrical signal dependent on the captured optical signal is generated by the photosensitive sensor 1224 and provided at the electrical connection 1326; the electrical connection 1326 provides a first electrical input/output interface (I/O 22) 1326.

The various optical coupling elements enable the transmission of light, and thus high-speed data and high-speed clock signals, not only between multiple layers of a semiconductor chip, but also between multiple stacked semiconductor substrates, such as semiconductor chips.

The above-described components or building blocks (for example, continuous-curvature coupling elements, 45° angle elements, 35.26° angle elements and 54.74° angle elements, deposited metal filters, optical lenses printed directly on, for example, the optical vias, e.g. made of silicon, etc.) printed optical lenses or optical meta-structures can be combined to achieve different degrees of interconnection between vertical and horizontal optical interconnects (e.g. in the form of waveguide structures) and between multiple semiconductor substrates, e.g. semiconductor chips in a semiconductor chip stack.

It should be noted that angle elements with any angle of curvature, for example any angle of curvature in a region greater than 0° and less than 360°, for example in a region greater than 0° and less than 180°, for example in a region greater than 0° and less than 90°. In principle, the coupling element can also have any shape, also depending on the design requirements of the respective semiconductor assembly, e.g. in a chip stack). For example, the coupling element can also have an elliptical shape.

By using a shielding structure (e.g. a metal filter) over an optical coupling element, unwanted data loss or data theft can be prevented.

The range of optical coupling elements enables continuous optical connections for both intra-substrate stacks (e.g. intra-chip stacks) and inter-substrate stacks (e.g. inter-chip stacks):
1. Three-way connection (customizable data/energy dividing), see for example semiconductor assembly 1000 according to FIG. 10:
   a. Three-way signal and power connection (input=100%; output 1=50%, output 2=50%)
   b. Three-way connection for variable signals and power (input=100%; output 1=1%, output 2=99%) (or output 1=99%, output 2=1% or any value in between).
2. Bidirectional connection of optical signals through lenses and other meta-structures enables light manipulation to produce optical signal transmissions—connections from one to many (several) semiconductor substrates (e.g. semiconductor chips) in a multi-chip stack (focused light and lower loss); see for example section of semiconductor assembly 100 according to FIG. 4.
3. Blocked optical connection to another semiconductor substrate (e.g. semiconductor chip) by blocking the light transmission at a continuous connection of the optical through-hole (also referred to as optical via connection) (input=100%; output=0%) (blind via—focus on chip safety); see, for example, semiconductor assembly 800 according to FIG. 8.
4. Blocked connection to the overlying semiconductor substrate (e.g. semiconductor chip) by blocking light transmission via the connection of a coupling element while enabling light transmission via the angled connection; see, for example, semiconductor assembly 700 according to FIG. 7.

Various aspects of this disclosure provide:
A variety of coupling elements provide a new way of connecting multiple optical waveguides on a semiconductor substrate, such as a semiconductor chip.
The design of the coupling elements enables rerouting of optical signals with different signal strengths.
Using directly positioned lenses and meta-structures to manipulate light to achieve power-efficient multi-chip interconnects is one way to route power from a light source to one or more photosensitive receivers, essentially optical signal transmission.
Directly positioned lenses and meta-structures can also be used as an optical clock transmission technique from a light source to one or more photosensitive receivers on the one semiconductor substrate stack, for example semiconductor chip stack, to form a precise clock transmission network.
In the case of heterogeneous integration, a semiconductor substrate stack, e.g. semiconductor chip stack, usually consists of different semiconductor substrates, e.g. semiconductor chips from several manufacturers (foundries). It is important to secure the data while enabling low latency and high bandwidths. Various aspects of this disclosure make it possible to prevent the optical through-connections with shielding structures, for example metal filters, to prevent unwanted data leakage or data theft without additional restrictions. Such a solution makes the optical connections tap-proof.

Various aspects of the present disclosure achieve one or more of the following technical effects:
An uninterruptible, all-optical connection between multiple semiconductor substrates, e.g. semiconductor chips, is possible by a combination of the optical coupling elements described above.
The large selection of optical coupling elements makes it possible to redirect the optical signal depending on the system requirements.

By accessing the various optical coupling elements described, optical connections with low space requirements, low latency and high bandwidth are guaranteed.
Now an undisturbed optical connection between a fiber optic backbone channel for global communication directly to the active region of the semiconductor substrate, e.g. the semiconductor chip, is possible. This direct connection is necessary for the requirements of the next generation of computers (essential for applications such as high performance computing and quantum computing).

Some examples are shown below.

Example 1 is a semiconductor assembly. The semiconductor assembly may comprise a first semiconductor substrate having a front surface and a back surface opposite to the front surface, the first semiconductor substrate comprising a first through-hole extending from the front surface to the back surface of the first semiconductor substrate, wherein a first optical waveguide structure is formed in the first through-hole for guiding optical waves between the front surface and the back surface of the first semiconductor substrate; and a second semiconductor substrate having a front surface and a back surface opposite to the front surface, the second semiconductor substrate comprising a second through-hole extending from the front surface to the back surface of the second semiconductor substrate, wherein a second optical waveguide structure is formed in the second through-hole for guiding optical waves between the front surface and the back surface of the second semiconductor substrate; wherein the first semiconductor substrate and the second semiconductor substrate are arranged at a distance from each other and such that optical waves coupled out from the first optical waveguide structure are coupled into the second optical waveguide structure. The semiconductor assembly may further comprise at least one first optical lens or at least one first optical meta-structure configured to refract the optical waves coupled out from the first optical waveguide structure in the direction of the second optical waveguide structure, and/or at least one second optical lens or at least one second optical meta-structure configured to refract the optical waves coupled out from the first optical waveguide structure in the direction of the second optical waveguide structure.

In example 2, the article of example 1 may optionally comprise that the at least one first optical lens or the at least one first optical meta-structure is monolithically integrated with the first optical waveguide structure; and/or that the at least one second optical lens or the at least one second optical meta-structure is monolithically integrated with the second optical waveguide structure.

In example 3, the subject matter of any of examples 1 or 2 may optionally comprise that the first semiconductor substrate and/or the second semiconductor substrate are configured as semiconductor chip(s).

In example 4, the subject matter of example 3 may optionally comprise that the first semiconductor substrate and/or the second semiconductor substrate is/are configured as logic semiconductor chip(s).

In example 5, the subject matter of any one of examples 1 to 4 may optionally comprise that the first through-hole and/or the second through-hole are/is filled with a first material forming a waveguide core of the first optical waveguide structure and/or a waveguide core of the second optical waveguide structure.

In example 6, the subject matter of example 5 may optionally comprise that the first material is a first polymeric material. The first material may also be another material, such as a semiconductor material (e.g., silicon (Si), silicon oxide (SiO₂₎, silicon nitride (Si_{(3)N4)}, indium phosphide (InP), lithium niobium (LiNb), and the like).

In example 7, the subject matter of any of examples 1 to 6 may optionally comprise that the first optical lens or the first optical meta-structure and/or the second optical lens or the second optical meta-structure are/is formed of a second polymeric material. The second material may also be another material, for example a semiconductor material (e.g. silicon (Si), silicon oxide (SiO₂₎, silicon nitride (Si_{(3)N4)}, indium phosphide (InP), lithium niobium (LiNb), and the like).

In example 8, the article of any one of examples 1 to 5 and examples 6 and 7 may optionally comprise that the first material (e.g., the first polymeric material) and the second material (e.g., the second polymeric material) are the same polymeric material.

In example 9, the article of any one of examples 1 to 8 may optionally comprise that the first through-hole and/or the second through-hole are bounded by a waveguide cladding for total reflection of optical waves guided in the first through-hole and/or in the second through-hole.

In example 10, the article of any one of examples 1 to 9 may optionally comprise that the at least one first optical lens and/or the at least one second optical lens is/are configured as a spherical lens.

In example 11, the subject matter of any one of examples 1 to 9 may optionally comprise the at least one first optical lens and/or the at least one second optical lens being configured as an aspherical lens.

In example 12, the article of any one of examples 1 to 11 may optionally comprise the first through-hole and/or the second through-hole having a diameter in a region of about 8 μm to about 10 μm.

In example 13, the article of any one of examples 1 to 11 may optionally comprise the first through-hole and/or the second through-hole having a diameter in a region from about 20 μm to about 200 μm, for example in a region from about 40 μm to about 100 μm.

In example 14, the article of any one of examples 1 to 13 may optionally comprise the at least one first optical lens and/or the at least one second optical lens having a diameter in a region from about 10 μm to about 300 μm, for example in a region from about 30 μm to about 120 μm.

In example 15, the article of example 14 may optionally comprise the at least one first optical lens and/or the at least one second optical lens having a diameter in a region of from about 2 μm to about 14 μm, for example in a region of from about 4 μm to about 10 μm.

In example 16, the article of any one of examples 1 to 15 may optionally comprise the first optical waveguide structure and/or the second optical waveguide structure being configured to be an optical waveguide.

In example 17, the subject matter of any one of examples 1 to 16 may optionally comprise the semiconductor assembly further comprising a third semiconductor substrate having a front surface and a back surface opposite the front surface, the third semiconductor substrate having a third through-hole extending from the front surface of the third semiconductor substrate, extending from the front surface of the third semiconductor substrate to the back surface of the third semiconductor substrate, wherein a third optical waveguide structure is formed in the third through-hole for guiding optical waves between the front surface of the third semiconductor substrate and the back surface of the third Semiconductor substrate; wherein the third semiconductor substrate is disposed on the side of the first semiconductor substrate that is distal from the second semiconductor substrate; wherein the first semiconductor substrate and the third semiconductor substrate are disposed at a distance from each other and such that optical waves coupled out from the first optical waveguide structure are coupled into the third optical waveguide structure; and at least one third optical lens or at least one third optical meta-structure configured to refract the optical waves coupled out from the first optical waveguide structure in the direction of the third optical waveguide structure.

In example 18, the article of example 17 may optionally comprise the at least one third optical lens or the at least one third optical meta-structure being monolithically integrated with the third optical waveguide structure.

In example 19, the subject matter of any one of examples 17 or 18 may optionally comprise that the third optical waveguide structure is configured to be an optical waveguide.

In example 20, the subject matter of any one of examples 1 to 19 may optionally comprise an additional optical waveguide structure disposed on the first semiconductor substrate and/or on the second semiconductor substrate; wherein the semiconductor assembly further comprises an angled optical connection for optically connecting the additional optical waveguide structure to the first optical waveguide structure or to the second optical waveguide structure.

Example 21 is a semiconductor package. The semiconductor package may comprise a semiconductor assembly according to any one of examples 1 to 20; and encapsulation material encapsulating the semiconductor assembly.

Example 22 is a semiconductor assembly. The semiconductor assembly may comprise a semiconductor substrate having an optical waveguide structure disposed thereon; and a shielding structure attached to the optical waveguide structure opposite the semiconductor substrate configured to shield energy emanating from the optical waveguide structure, wherein the shielding structure is in physical contact with the optical waveguide structure.

In example 23, the subject matter of example 22 may optionally comprise that the shielding structure comprises metal and is configured to shield energy emanating from the optical waveguide structure. The metal shielding structure shields and also reflects the energy emerging from the optical waveguide structure.

In example 24, the subject matter of example 22 may optionally comprise wherein the shielding structure comprises polymeric material and is configured to shield energy emanating from the optical waveguide structure. The shielding structure of polymeric material shields the energy exiting the optical waveguide structure.

In example 25, the subject matter of any one of examples 22 to 24 may optionally comprise that the semiconductor substrate has a through-hole extending from a front side of the semiconductor substrate to a back side of the semiconductor substrate, wherein a through-hole optical waveguide structure is formed in the through-hole for guiding optical waves between the front side and the back side of the semiconductor substrate; that the semiconductor assembly further comprises an angled optical connection for optically connecting the through-hole optical waveguide structure to the through-hole optical waveguide structure; that the shielding structure extends at least partially on the angled optical connection for shielding energy leaking from the angled optical connection.

In example 26, the article of any one of examples 22 to 25 may optionally comprise the shielding structure comprising metal or being formed of a metal.

In example 27, the article of example 26 may optionally comprise the metal having a layer thickness in a region from about 50 nm to about 600 nm, for example in a region from about 150 nm to about 350 nm, for example a layer thickness of about 300 nm.

In example 28, the subject matter of any one of examples 22 to 27 may optionally comprise the semiconductor substrate being configured as a semiconductor chip.

In example 29, the subject matter of example 28 may optionally comprise that the semiconductor substrate is configured as a logic semiconductor chip.

In example 30, the subject matter of any one of examples 22 to 29 may optionally comprise that a waveguide core of the optical waveguide structure is formed of a polymer material. The waveguide core of the optical waveguide structure may also be formed of one or more other materials, for example, a semiconductor material (e.g., silicon (Si), silicon oxide (SiO₂₎, silicon nitride (Si_{(3)N4)}, indium phosphide (InP), lithium niobate (LiNbO₃₎, and the like).

In example 31, the article of example 30 may optionally comprise that the optical waveguide structure is bounded by a waveguide cladding for total reflection of optical waves guided in the optical waveguide structure.

In example 32, the article of any one of examples 25 to 31 may optionally comprise the first through-hole and/or the second through-hole having a diameter in a region of about 4 μm to about 12 μm, for example in a region of about 6 μm to about 10 μm.

In example 33, the article of any one of examples 25 to 31 may optionally comprise the through-hole having a diameter in a region from about 20 μm to about 200 μm, for example in a region from about 40 μm to about 100 μm.

In example 34, the subject matter of any one of examples 22 to 33 may optionally comprise the optical waveguide structure being configured to be an optical waveguide.

Example 35 is a semiconductor package. The semiconductor package may comprise a semiconductor assembly according to any one of examples 22 to 34; and encapsulation material encapsulating the semiconductor assembly.

Example 36 is a semiconductor package. The semiconductor package may comprise a semiconductor assembly according to any one of examples 1 to 20; and a semiconductor assembly according to any one of examples 22 to 34; and encapsulating material encapsulating the semiconductor assemblies.

Example 37 is a semiconductor assembly. The semiconductor assembly may comprise a semiconductor substrate having an optical waveguide structure disposed thereon; the semiconductor substrate having a through-hole extending from a front surface of the semiconductor substrate to a back surface of the semiconductor substrate, wherein a through-hole optical waveguide structure is formed in the through-hole for guiding optical waves between the front surface and the back surface of the semiconductor substrate; the semiconductor assembly further comprising an angled optical connection for optically connecting the optical waveguide structure to the through-hole optical waveguide structure, wherein the angled optical connection is configured as an optical beam splitter for dividing optical waves into a first portion and a second portion, the first portion being coupled into the through-hole optical waveguide structure; and an additional optical waveguide structure coupled to the angled optical connection such that the second portion is coupled into the additional optical waveguide structure.

In example 38, the subject matter of example 37 may optionally comprise the additional optical waveguide structure being disposed on the semiconductor substrate.

In example 39, the subject matter of any one of examples 37 or 38 may optionally comprise that the semiconductor substrate is configured as a semiconductor chip.

In example 40, the subject matter of example 39 may optionally comprise that the semiconductor substrate is configured as a logic semiconductor chip.

In example 41, the subject matter of any one of examples 37 to 40 may optionally comprise a waveguide core of the optical waveguide structure being formed of a polymeric material. The waveguide core of the optical waveguide structure may also be formed of one or more other materials, such as a semiconductor material (e.g., silicon (Si), silicon oxide (SiO₂₎, silicon nitride (Si_{(3)N4)}, indium phosphide (InP), lithium niobate (LiNbO₃₎, and the like).

In example 42, the article of example 41 may optionally comprise the optical waveguide structure being bounded by a waveguide cladding for total reflection of optical waves guided in the optical waveguide structure.

In example 43, the article of any one of examples 37 to 42 may optionally comprise the first through-hole and/or the second through-hole having a diameter in a region from about 4 μm to about 12 μm, for example in a region from about 6 μm to about 10 μm.

In example 44, the article of any one of examples 37 to 42 may optionally comprise the through-hole having a diameter in a region from about 20 μm to about 200 μm, for example in a region from about 40 μm to about 100 μm.

In example 45, the article of any one of examples 37 to 44 may optionally comprise that the optical waveguide structure and/or the additional optical waveguide structure is/are configured to be an optical waveguide.

Example 46 is a semiconductor package. The semiconductor package may comprise a semiconductor assembly according to any one of examples 37 to 45; and encapsulation material encapsulating the semiconductor assembly.

Example 47 is a semiconductor package. The semiconductor package may comprise a semiconductor assembly according to any one of examples 1 to 20; a semiconductor assembly according to any one of examples 37 to 45; and encapsulation material encapsulating the semiconductor assemblies.

Example 48 is a semiconductor package. The semiconductor package may comprise a semiconductor assembly according to any one of examples 22 to 34; a semiconductor assembly according to any one of examples 37 to 45; and encapsulating material encapsulating the semiconductor assemblies.

Example 49 is a semiconductor package. The semiconductor package may comprise a semiconductor assembly according to any one of examples 1 to 20; a semiconductor assembly according to any one of examples 22 to 34; a semiconductor assembly according to any one of examples 37 to 45; and encapsulating material encapsulating the semiconductor assemblies.

1. A semiconductor assembly comprising:
a first semiconductor substrate having a front surface and a back surface opposite the front surface, the first semiconductor substrate comprising a first through-hole extending from the front surface to the back surface of the first semiconductor substrate, wherein a first optical waveguide structure is formed in the first through-hole for guiding optical waves between the front surface and the back surface of the first semiconductor substrate;
a second semiconductor substrate having a front surface and a back surface opposite to the front surface, the second semiconductor substrate comprising a second through-hole extending from the front surface to the back surface of the second semiconductor substrate, wherein a second optical waveguide structure is formed in the second through-hole for guiding optical waves between the front surface and the back surface of the second semiconductor substrate,
wherein the first semiconductor substrate and the second semiconductor substrate are spaced apart from each other and arranged for coupling optical waves from the first optical waveguide structure into the second optical waveguide structure; and
at least one first optical lens or at least one first optical meta-structure configured to refract the optical waves coupled out from the first optical waveguide structure toward the second optical waveguide structure, or at least one second optical lens or at least one second optical meta-structure configured to refract the optical waves coupled out from the first optical waveguide structure toward the second optical waveguide structure.

2. The semiconductor assembly according to claim 1,
wherein the at least one first optical lens or the at least one first optical meta-structure is monolithically integrated with the first optical waveguide structure, or
wherein the at least one second optical lens or the at least one second optical meta-structure is monolithically integrated with the second optical waveguide structure.

3. The semiconductor assembly according to claim 1,
wherein the first semiconductor substrate or the second semiconductor substrate is configured as a semiconductor chip.

4. The semiconductor assembly according to claim 3,
wherein the first semiconductor substrate or the second semiconductor substrate is configured as a logic semiconductor chip.

5. The semiconductor assembly according to claim 4,
wherein the first through-hole or the second through-hole is filled with a first material forming a waveguide core.

6. The semiconductor assembly according to claim 5,
wherein the first material is a first polymer material.

7. The semiconductor assembly according to claim 5,
wherein the at least one first optical lens or the at least one first optical meta-structure is formed of a second polymer material, or wherein the second optical lens or the second optical meta-structure is formed of the second polymer material.

8. The semiconductor assembly according to claim 7,
wherein the first material is a first polymer material, wherein the first polymer material and the second polymer material are the same polymer material.

9. The semiconductor assembly according to claim 1,
wherein the first through-hole or the second through-hole is bounded by a waveguide cladding for total reflection of the optical waves guided therein.

10. The semiconductor assembly according to claim 1,
wherein the at least one first optical lens or the at least one second optical lens is configured as a spherical lens.

11. The semiconductor assembly according to claim 1,
wherein the at least one first optical lens or the at least one second optical lens is configured as an aspherical lens.

12. The semiconductor assembly according to claim 1,
wherein a diameter of the first through-hole or of the second through-hole is about 4 μm to about 12 μm.

13. The semiconductor assembly according to claim 1,
wherein a diameter of the first through-hole or of the second through-hole is about 20 μm to about 200 μm.

14. The semiconductor assembly according to claim 1,
wherein a diameter of the at least one first optical lens or of the at least one second optical lens is about 10 μm to about 300 μm.

15. The semiconductor assembly according to claim 14,
wherein a first diameter of the at least one first optical lens or the at least one first optical meta-structure is about 2 μm to about 14 μm, or wherein a second diameter of the at least one second optical lens or the at least one second optical meta-structure is about 2 μm to about 14 μm.

16. The semiconductor assembly according to claim 1,
wherein the first optical waveguide structure or the second optical waveguide structure is configured to be an optical waveguide.

17. The semiconductor assembly according to claim 1, further comprising:
a third semiconductor substrate having a front surface and a back surface opposite the front surface, the third semiconductor substrate having a third through-hole extending from the front surface to the back surface of the third semiconductor substrate, wherein a third optical waveguide structure is formed in the third through-hole for guiding optical waves between the front surface and the back surface of the third semiconductor substrate,
wherein the third semiconductor substrate is disposed on a side of the first semiconductor substrate that is distal to the second semiconductor substrate,
wherein the first semiconductor substrate and the third semiconductor substrate are arranged at a distance from each other for coupling optical waves from the first optical waveguide structure into the third optical waveguide structure; and
at least one third optical lens configured to refract the optical waves coupled out from the first optical waveguide structure toward the third optical waveguide structure.

18. The semiconductor assembly according to claim 17,
wherein the at least one third optical lens or the at least one third optical meta-structure is monolithically integrated with the third optical waveguide structure.

19. The semiconductor assembly according to claim 17,
wherein the third optical waveguide structure is configured to be an optical waveguide.

20. The semiconductor assembly according to claim 1,
wherein an additional optical waveguide structure is arranged on the first semiconductor substrate or on the second semiconductor substrate,
wherein the semiconductor assembly further comprises an angled optical connection for optically connecting the additional optical waveguide structure to the first optical waveguide structure or to the second optical waveguide structure.

21. (canceled)
